(19) United States
(12) Patent Application Publication
(10) Pub. No.: US 2025/0266530 A1
(43) Pub. Date: Aug. 21, 2025

(54) Battery-Charging Devices Having Thermally Conductive Thermal-Management Systems for Managing Battery Temperature During Charging Operations, and Related Methods

(71) Applicant: SES (Shanghai) Co. Ltd., Shanghai (CN)

(72) Inventors: Jiwei Liang, Shanghai (CN); Xianjie Wang, Shanghai (CN); Chengcheng Zheng, Shanghai (CN)

(21) Appl. No.: 18/608,647

(22) Filed: Mar. 18, 2024

(30) Foreign Application Priority Data
Feb. 19, 2024 (CN) 2024101862023

(51) Int. Cl. H01M 10/6572; H01M 10/63; H02J 7/00; H05K 7/20

(52) U.S. Cl. CPC H01M 10/6572; H01M 10/63; H02J 7/0042; H02J 7/007192; H05K 7/20154; H05K 7/20209

(57) ABSTRACT

Battery-charging devices having thermal-management systems that each include one or more thermoelectric devices used to manage the temperature of one or more secondary batteries during charging operations. Each thermoelectric device is operated to cool and/or heat the corresponding battery(ies) using the Peltier effect. The transfer of heat between the battery(ies) and the corresponding thermoelectric device(s) is by thermal conduction via a thermal-conduction interface between the battery(ies) and the corresponding thermoelectric device(s). Related methods of charging batteries are also disclosed.

### FIELD

The present disclosure generally relates to devices for charging secondary batteries. More particularly, the present disclosure is directed to battery-charging devices having thermally conductive thermal-management systems for managing battery temperature during charging operations, and related methods.

### BACKGROUND

Conventional battery chargers often manage heat generated by batteries during charging using either forced-air cooling or forced-liquid cooling. Forced-air cooling schemes can be problematic because ambient air used for cooling can contain dust and/or other contaminant(s) and can also or alternatively carry excessive amounts of moisture. Consequently, when the ambient air is flowed through internal parts of the battery chargers, the contaminants and/or moisture can cause fouling and/or damage to the batteries being charged and/or components of the chargers, such as circuit boards, among others. Forced-liquid cooling schemes can be problematic due to the additional components and complexity that come with providing liquid-coolant passageways, fittings, pumps, and other cooling-system components, not to mention the potential damage that can occur when the liquid coolant leaks from the cooling systems.

### SUMMARY

In one implementation, the present disclosure is directed to a battery-charging device for charging a secondary battery that includes electrical terminals and a heat-transfer face. The battery-charging device includes a charging region that receives the secondary battery during a charging operations; a charging system that, when the secondary battery is present in the charging region, electrically connects to the electrical terminals of the secondary battery and charges the secondary battery during the charging operations; a thermal-management system that includes: a thermal-conduction interface that contactingly receives the heat-transfer face of the secondary battery when the battery is located in the charging region so that heat can be conducted between the secondary battery and the thermal management system during the charging operations; a heat sink/source; and a thermoelectric device thermally coupled between the thermal-conduction interface and the heat sink/source, wherein during the charging operations with the secondary battery located in the charging region, the thermoelectric device transfers heat between the secondary battery and the heat sink/source.

In another implementation, the present disclosure is directed to a method of charging a secondary battery. The method includes causing a battery-charging device to perform charging operations upon the secondary battery; and during the charging operations, causing a thermoelectric device, that is directly thermally coupled to the secondary battery, to transfer heat between the secondary battery and a heat sink/source by thermal conduction.

### BRIEF DESCRIPTION OF THE DRAWINGS

For the purpose of illustration, the accompanying drawings show aspects of one or more embodiments of the disclosure. However, it should be understood that the scope of this disclosure is/are not limited to the precise arrangements and instrumentalities shown in the drawings, wherein:

FIG. 1 is a high-level schematic/block diagram of an example battery-charging device made in accordance with aspects of the present disclosure;

FIG. 2 is an isometric view of an example battery-charging device of the present disclosure configured to charge two battery packs in corresponding respective charging compartments;

FIG. 3 is an exploded isometric view of the battery-charging device of FIG. 2;

FIG. 4 is an enlarged cross-sectional view of each of the battery packs operatively engaged with a corresponding one of thermal-management components of the battery-charging device of FIGS. 2 and 3, shown in FIG. 4 in isolation from other components of the battery-charging device; and

FIG. 5 is a further enlarged partial cross-sectional view of the battery pack and the thermal-management component of the battery-charging device of FIGS. 1 and 2 as taken at detail region A of FIG. 4.

### DETAILED DESCRIPTION

The technical content of the appended claims are incorporated by reference into this Detailed Description section so that they are included herein as if they were literally present in this section.

### General

In some aspects, the present disclosure is directed to battery-charging devices for electrically charging secondary batteries of any of a variety of types and any of a variety of chemistries, wherein each battery-charging device includes at least one thermoelectric device that is directly thermally coupled to each of the one or more secondary batteries that are charged by the battery-charging device. Examples of secondary battery types that can be used with a battery-charging device of this disclosure include, but are not limited to, secondary batteries that include one or more pouch cells or one or more cylindrical cells, among others. Examples of battery chemistries include, but are not limited to, chemistries based on one or more alkali metals, such as lithium, sodium, and potassium, chemistries based on sulfur, and chemistries based on nickel, among others, and may be of the intercalating-de-intercalating type, the plating-stripping type, or any combination thereof, among others. Fundamentally, there is no limitation on the type of secondary batteries suitable for use with a battery-charging device of this disclosure other than that it can be electrically charged and that the temperature of the secondary battery may need to be controlled during charging operations. In this disclosure and in the appended claims, the term “secondary battery” and “battery”, unless noted otherwise, is broadly used to denote a rechargeable electrochemical device of any form, including, but not limited to an electrochemical cell, a battery module containing one or more electrochemical cells, and a battery pack comprising one or more battery modules, among others.

As used herein and in the appended claims, the term “thermoelectric device” denotes a solid-state device that, when electrically powered, exhibits the well-known Peltier phenomenon that results in a temperature difference at the junction of two dissimilar materials. Thermoelectric devices are typically made of two dissimilar semiconductor materials, such as bismuth telluride and antimony telluride, that, when a DC voltage is applied to them, experience electron flow from one of the semiconductor materials to the other across the junction, causing one of the semiconductor materials to absorb heat and the other semiconductor material to reject heat. Controlling the absolute magnitude of the DC voltage, within limits, controls the magnitude of the temperature-change-causing electron flow within the thermoelectric device, thereby controlling the amounts of heat absorption and heat rejection. Controlling the direction of the DC voltage controls the absorption-rejection behavior of the two materials, thereby controlling the ability of each side of the junction to provide heat or absorb heat.

In some aspects, the present disclosure is directed to methods of performing charging operations for electrically charging a secondary battery that is in direct thermal contact with a thermoelectric device. In an example, a method of the present disclosure includes causing a battery-charging device to perform charging operations upon a secondary battery. During the charging operations, a thermoelectric device that is directly thermally coupled to the secondary battery is caused to transfer heat between the secondary battery and a heat sink/source by thermal conduction. In some embodiments, if the secondary battery is initially at a temperature below a preset minimum charging temperature, the thermoelectric device is operated to provide heat to the secondary battery to raise the temperature of the battery to the minimum charging temperature or above. When the temperature of the secondary battery rises above a maximum charging temperature during charging, the thermoelectric device is operated to remove heat from the secondary battery to drop the temperature of the secondary battery to or below the maximum charging temperature. Other methods are disclosed. The foregoing and other aspects of the present disclosure are described below in detail.

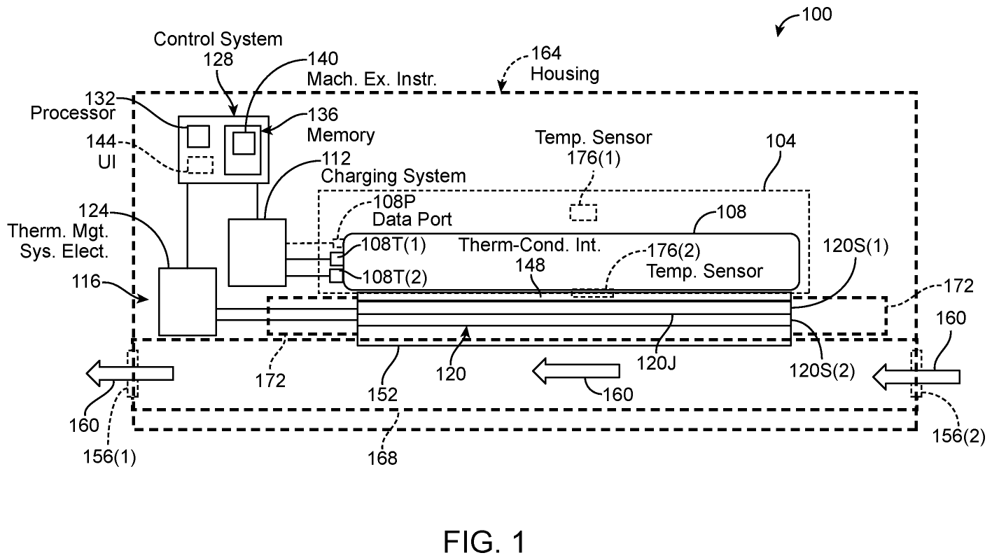

Referring now to the drawings, FIG. 1 shows an example battery-charging device 100 that includes various features of the present disclosure. In this example, the battery charging device 100 includes a charging region 104 configured to a secondary battery 108 (hereinafter, simply “battery”) for performing charging operations so as to charge the battery. As noted above, the battery 108 can be any of a variety of battery devices in any of a variety of forms. In this example, the battery 108 is a battery module having positive and negative electrical terminals 108T(1) and 108T(2) in electrical communication with the battery core (not shown) within the battery. The battery-charging device 100 has a charging system 112 that, during the charging operations, is electrically connected to the electrical terminals 108T(1) and 108T(2) of the battery 108 and that include all of the necessary electronics (not shown), which includes any necessary control software and/or hardware for charging the battery using any one or more of a variety of charging protocols, including, but not limited to a constant-current constant-voltage protocol, a multistage constant current protocol, and/or a constant-current+pulsed charging protocol, among others. Those skilled in the art are readily familiar with charging protocols and corresponding electronics that can be used in the charging system 112 such that further details are not needed herein for those of ordinary skill in the art to make and use a battery-charging device of the present disclosure, such as the battery-charging device 100 of FIG. 1.

The battery-charging device 100 of this example also includes a thermal-management system 116 that comprises one or more thermoelectric devices (singly and collectively shown at thermoelectric device(s) 120) and thermal-management-system electronics 124 for operating the thermoelectric device(s). Each thermoelectric device 120 includes first and second sides 120S(1) and 120S(2), made of dissimilar materials, that form a junction 120J as noted above. As discussed above, the dissimilar materials of the first and second sides may be, for example, any suitable dissimilar semiconductor materials, such as, but not limited to, bismuth telluride and antimony telluride, among others. Those skilled in the art will be readily familiar with thermoelectric devices suitable for use as any thermoelectric device(s) 120 of a battery-charging device of the present disclosure, such as the battery-charging device 100 of FIG. 1, such that further details are not needed herein for those of ordinary skill in the art to make and use such a battery-charging device.

The thermal-management-system electronics 124 includes any and all components needed to power and control the operation of the thermoelectric device(s) 120, such as, but not limited to, one or more DC power supplies (not shown), such as one or more variable-voltage DC power supplies, and any necessary support electronics (not show). Thermoelectric devices and thermal-management-system electronics suitable for use in the thermal-management system 116 are well-known such that further details are not needed herein for those of ordinary skill in the art to make and use a battery-charging device of the present disclosure, such as the battery-charging device 100 of FIG. 1.

In this example, the battery-charging device 100 further includes a control system 128, which is configured to control the overall operations of the battery-charging device partially or fully automatedly, including controlling each of the charging system 112 and the thermal-management system 116 so that the battery-charging device performs the desired charging operations. In some embodiments, the charging operations include stopping and starting charging, for example, stopping and/or starting charging in conjunction with controlling the thermal-management system 116. For example, in some situations, the battery 108 is optimally charged when the temperature of the battery is at or above a minimum charging temperature. If the battery 108 is below the minimum charging temperature before charging begins, for example, when the battery is first placed into the battery-charging region 104, then the control system 128 may cause the thermal-management system 116 to operate the thermoelectric device(s) 120 in a manner to warm the battery to at least the minimum charging temperature before causing the charging system 112 to start charging the battery. As another example, if the battery 108 is above a maximum charging temperature before charging begins, for example, when the battery is first placed into the battery-charging region 104, then the control system 128 may cause the thermal-management system 116 to operate the thermoelectric device(s) in a manner to cool the battery to at most the maximum charging temperature before causing the charging system 112 to start charging the battery.

As a further example, charging the battery 108 can cause the battery 108 to heat up. Consequently, during charging operations, when the control system 128 determines that the temperature of the battery 108 has exceeded the maximum charging temperature, it may then cause the thermal-management system 116 to operate the thermoelectric device(s) 120 in a manner that removes heat from the battery, for example, until the temperature of the battery has fallen below the maximum charging temperature. The control scheme that the control system 128 uses to cause the thermal-management system 116 to keep the battery 108 within a charging-temperature range during charging may be any suitable control scheme. For example, the control system 128 may cause the thermal-management system 116 to keep the temperature of the battery 108 within a relatively narrow optimal-charging-temperature range by controlling the thermal-management system to operate nearly continuously during charging so as to essentially balance the amount of heat that the thermal-management system removes with the amount of heat that charging generates. As those skilled in the art will appreciate, this balancing may be accomplished using a tight temperature control loop that varies the DC voltage applied across the first and second sides 120S(1) and 120S(2) of the thermoelectric device(s) 120.

In another example, the control system 128 may cause the thermal-management system 116 to operate intermittently so as to cool the battery 108 to a relatively low temperature, such as close to the minimum charging temperature, and then allow the battery to heat up to a relatively high temperature, such as close to the maximum charging temperature, before causing the thermal-management system to reenergize the thermoelectrical device(s) 120. Those skilled in the art will appreciate that in an intermittent control scheme, the control system 128 may, in some embodiments, cause the thermal management system 116 to operate the thermoelectric device(s) 120 at or near its/their maximum DC voltage while it/they are energized so as to minimize the amount of cooling time. Those skilled in the art will readily appreciate that these example control schemes are merely examples and are not limiting and that the control system 128 may use any suitable control scheme(s) for controlling the temperature of the battery 108 during charging.

In the embodiment shown, the control system 128 includes a processor 132, one or more hardware memories (singly and collectively represented as memory 136) in operative communication with the processor, machine-executable instructions 140 stored in the memory and configured for execution by the processor, and any needed user interface (UI) 144. The processor 132 may be any suitable processor, such as, for example, system on chip or a microprocessor. In some embodiments, the processor 132, memory 136, and machine-executable instructions 140 may be embodied in specialized circuitry, such as a system on chip, an application-specific integrated circuit, or a field-programmable gate array, among other options. The memory 136 may be any one or more hardware memories, such as RAM, ROM, cache, magnetic, optical, bubble, etc. Fundamentally, there is no limitation on the type(s) of the memory 136 as long as it/they can store the machine-executable instructions 140 and can communicate the machine-executable instructions to the processor 132. In this connection, it is noted that the term “machine-readable hardware storage medium” as used herein and in any appended claim, means any hardware memory, standing alone or in combination with one another, that stores the machine-executable instructions, such as the machine-executable instructions 140, that cause any one or more processors, such as the processor 132, to perform the requisite functionality(ies). The term “machine-readable hardware storage medium” does not include transitory signals, such as signals containing digital information encoded onto carrier waves and signals containing digital information encoded in pulses.

If provided, the UI 144 may include any soft control(s), hard control(s), or combination of soft and hardware controls needed for performing the desired operation(s), as well as any needed electronic display needed to convey information visually to a user. For example, the UI 144 may include one or more controls for turning the battery-charging device 100 on and/or off, one or more controls for starting and/or stopping charging operations, one or more controls for imputing charging-operation parameters, such as type of the battery 108, capacity of the battery, maximum state of charge for charging, type of charging protocol, and minimum and/or maximum charging temperatures, among others. Those skilled in the art will readily understand what, if any, soft and/or hard controls to include for a particular implementation of the battery-charging device 100. In some embodiments, the battery-charging device 100 may be in operative communication with another device (not shown), such as a broader charging-system controller, laptop computer, etc., that provides UI functionality, including any one or more of the functionalities described above, such that the onboard UI 144 is not needed.

The machine-executable instructions 140 include machine-executable instructions for executing any or all of the control scheme(s) (e.g., as one or more algorithms) that the control system 128 is configured to perform, as well as for providing any or all of the functionality(ies) of the UI 144, if present, not to mention any other functionality(ies) that need to be performed, such as communicating with one or more offboard devices, among many others. Those skilled in the art will readily understand how to code any needed machine-executable instructions needed for performing the necessary control algorithm(s) (e.g., charging-operations control algorithm(s)) and for providing any other required functionality(ies) such that it is not necessary to describe the machine-executable instructions 140 in any further detail herein for those skilled in the art to make and use a battery-charging device of the present disclosure, such as the battery-charging device 100.

The thermal-management system 116 includes a thermal-conduction interface 148 between the battery 108 and thermoelectric device 120 so as to provide a direct contact-type coupling between the battery and the thermoelectric device to allow heat to be thermally conducted between the two elements. By “direct contact-type coupling” it is meant that the thermal-conduction interface 148 physically contacts both the battery 108 and the thermoelectric device 120 so that the transfer of heat between the battery and the thermoelectric device is by thermal conduction through the thermal-conduction interface. The thermal-conduction interface 148 may be composed of any one or more materials and disposed in any one or more layers. For example, in some embodiments, the thermal-conduction interface 148 may be a sheet, plate, or other structure composed of a highly thermally conductive material, such as a metal, among others. Alternatively, the thermal-conduction interface 148 may simply be a surface of the thermoelectric device 120 that physically contacts the battery 108. Fundamentally, there is no limitation on the physical embodiments of the thermal-conduction interface 148 other than it enables the transfer of heat between the battery 108 and the thermoelectric device 120 by thermal conduction to an extent that allows the proper cooling and/or heating of the battery contemplated by a battery-charging device of the present disclosure, such as the battery-charging device 100 of FIG. 1.

In some embodiments, the thermal-management system 116 also includes a heat sink/source 152 thermally conductively coupled to the thermoelectric device 120. The “sink/source” designation is intended to denote that the heat sink/source 152 functions as a heat sink or a heat source depending on the manner in which the control system 128 is controlling the operation of the thermoelectric device 120. That is, if the control system 128 is causing the thermal-management system 116 to remove heat from the battery 108, then the heat sink/source 152 functions as a heat sink to remove heat from the thermoelectric device 120. Conversely, if the control system 128 is causing the thermal-management system 116 to provide heat to the battery 108, then the heat sink/source 152 functions as a heat source to provide heat to the thermoelectric device 120. It is noted that any use of the designation “heat sink/source” herein or in the appended claims does not necessarily mean that the heat sink/source has to function as both a heat sink and a heat source. For example, some embodiments of a battery-charging device of the present disclosure may not include a battery-warming function and so many never utilize the heat sink/source as a heat source. In such an embodiment, the term “heat sink/source” shall be taken to mean only “heat sink”.

As with the thermal-conduction interface 148 when the thermal-conduction interface is a distinct physical structure, the heat sink/source 152 may be made of any one or more suitable thermally conductive materials, such as one or more metals, among others. In some embodiments, the heat sink/source 152 may include one or more types of features, such as fins, vanes, ridges, louvers, channels, passageways, etc., and any combination thereof, to increase the surface area exposed to the environment surrounding the heat sink/source to increase the heat-transfer efficiency of the heat sink/source as between the heat sink/source and the surrounding environment.

In this connection, in some embodiments the thermal-management system 116 may optionally include one or more fans 156(1) and/or 156(2) for moving ambient air (as indicated by arrows 160) across the heat sink/source 152 to increase the efficiency of heat transfer between the heat sink/source and the ambient air. Each of the one or more fans (here, fans 156(1) and 156(2)) may be located at any suitable location for moving the ambient air 160 across the heat sink/source 152. Although not illustrated in FIG. 1, each fan 156(1) and 156(2) provided may be controlled by the control system 128, for example, as a function of the temperature(s) of the first and/or second sides 120S(1) and 120S(2) of the thermoelectric device 120 and/or of the ambient air surrounding the battery-charging device 100 and/or the amount of heat needed to be removed from or added to the battery 108 and/or the thermoelectric device at any particular time.

In some embodiments, the battery-charging device 100 may be contained in an optional housing 164. If one or more fans, such as one or both of the fans 156(1) and 156(2), are provided, the thermal-management system 116 may further include an air passageway 168 for directing the ambient air 160 through the housing 164 and into contact with the heat sink/source 152. In some embodiments the air passageway 168 may include dedicated ducting, while in other embodiments the air passageway may be defined by other structures within the housing 164, such as one or more circuit boards (not shown), or one or more internal support structures, such as a battery support structure 172, or an interior surface of the housing, among other things.

As discussed above, the control system 128 can control the temperature of the battery 108 during charging operations. Consequently, the control system 128 must know the temperature of the battery 108. This may be accomplished in any one or more of manners. For example, if the battery 108 has one or more integrated temperature sensors (not shown), it may have a data port 108P for providing temperature data to the charging system 112 and/or to the control system 128. As another example, the battery-charging device 100 may have one or more integrated sensors, such as integrated temperature sensors 176(1) and 176(2), which may each be of any suitable type, such as a contact-type sensor or a standoff-type sensor. In the examples shown, the temperature sensor 176(1) is a standoff-type sensor, such as an infrared sensor, and the temperature sensor 176(2) is a contact-type sensor, such as a thermocouple.

In some embodiments in which the battery-charging device 100 includes the housing 164, the charging region 104 may be provided as a compartment within the housing, and, if provided, the compartment may include a suitable closure (not shown) that seals the compartment from the ambient environment. It is noted that while FIG. 1 illustrates the battery-charging device 100 as being designed for charging only a single battery 108 at a time, in other embodiments the battery-charging device may be modified to accommodate charging two or more batteries. For example, such a modified battery-charging device may include multiple charging regions like charging region 104, each designed and configured to receive a corresponding battery for charging. In this connection, the charging system 112 may be modified to accommodate the charging of as many batteries as the modified battery-charging device is designed to hold. In such multiple-battery embodiments, multiple independently operated thermoelectric devices, each the same as or similar to the thermoelectric device 120 of FIG. 1, may be provided and controlled collectively by the thermal-management-system electronics 124 or controlled independently by separate thermal-management-system electronics (not shown), which may all be controlled by the control system 128 for the entire battery-charging device.

### DETAILED EXAMPLES

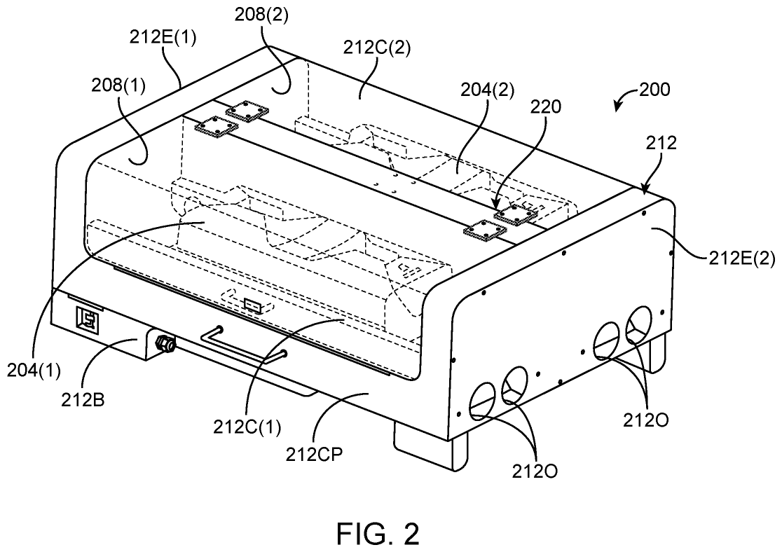

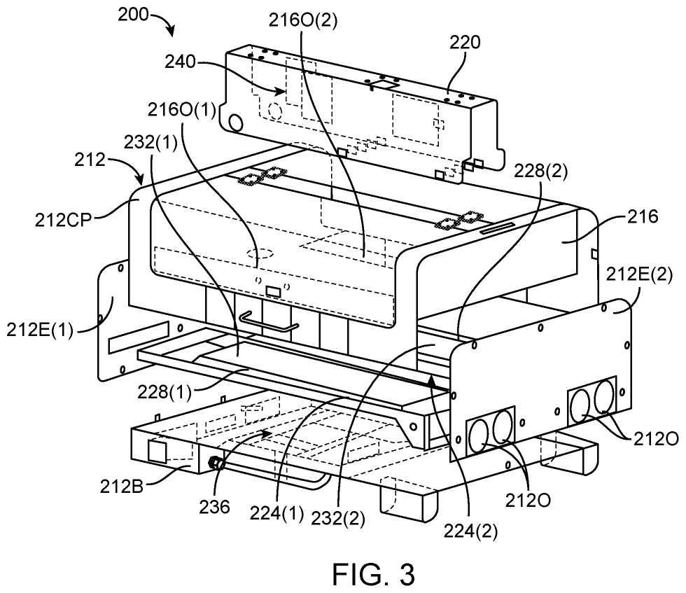

FIGS. 2 through 5 illustrate an example battery-charging device 200 that is designed and configured to charge two battery packs, or simply batteries, 204(1) and 204(2) in corresponding respective separate charging compartments 208(1) and 208(2). In this example and as best seen in FIGS. 2 and 3, the battery-charging device 200 includes a housing 212 having end walls 212E(1) and 212E(2) and an upper central portion 212CP extending between the end walls. A charging-compartment pan 216 and a central dividing structure 220 are located inside an upper portion of the housing 212. A pair of compartment closures 212C(1) and 212C(2) are hingedly attached to the central dividing structure 220.

A pair of thermal-management components 224(1) and 224(2) extends between, and is supported by, the end wall 212E(1) and 212E(2). The charging-compartment pan 216 includes a pair of openings 2160(1) and 2160(2) that receive therethrough corresponding parts of the thermal-management components 224(1) and 224(2), namely, portions of first and second thermoelectric devices 228(1) and 228(2) and corresponding first and second thermal-conduction interfaces 232(1) and 232(2). Each of the compartment closures 212C(1) and 212C(2), corresponding one of the thermal-conduction interfaces 232(1) and 232(2), corresponding faces of the central dividing structure 220, and corresponding faces of the charging-compartment pan 216 define the corresponding charging compartment 208(1), 208(2), each of which comprises a corresponding charging region (not labeled) that is similar to the charging region 104 of FIG. 1.

As best seen in FIG. 3, the housing 212 includes a base 212B, which contains various electronics 236 for assisting with making the battery-charging device 200 operational. As also seen in FIG. 3, the central dividing structure 220 also includes electronics 240 for assisting with making the battery-charging device 200 operational. Without going into detail, the electronics 236 and 240 includes electronics for a charging system, such as the charging system 112 of FIG. 1, thermal-management-system electronics, such as the thermal-management-system electronics 124 of FIG. 1, and a control system, such as the control system 128 of FIG. 1, and any other necessary electronics, such as one or more power supplies, among others.

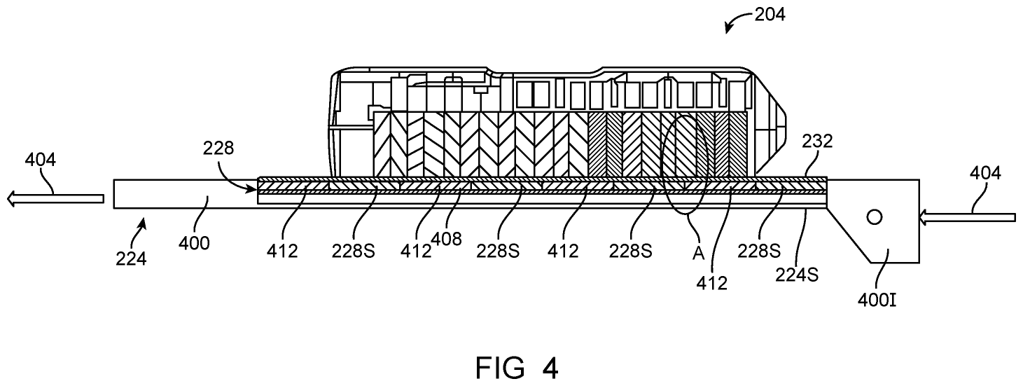

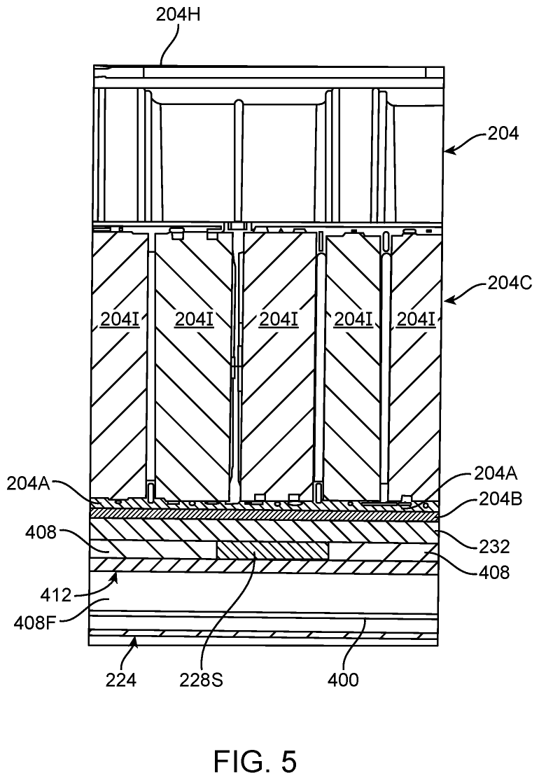

FIG. 4 shows each of the example batteries 204(1) and 204(2) (identified in FIGS. 4 and 5 as “battery 204” in the singular for simplicity) operatively engaged with the corresponding one of the thermal-management components 224(1) and 224(2) (identified in FIGS. 4 and 5 as “thermal-management component 224” in the singular for simplicity). As seen in FIG. 4, the thermal-management component 224 includes a support structure 224S that supports, among other things, the thermoelectric device 228 (228(1) and 228(2) in FIG. 3) and the battery 204 when it is engaged with the thermal-management component. In this embodiment, the support structure 224S defines an air duct 400 that flows air (represented by arrows 404) in contact with a heat sink/source 408 that is thermally coupled to the thermoelectric device 228. The air duct 400 includes an inlet end 400I that is enlarged to accommodate the physical size of fans (not shown) that draw ambient air from outside the battery-charging device 200 (FIGS. 2 and 3). In this connection and referring back to FIGS. 2 and 3, each of these figures shows two pairs of openings 2120 in the housing end wall 212E(2) over which corresponding pairs of fans (not shown) are mounted to force ambient air into the inlet end 400I of the air duct 400 of each of the thermal-management components 224(1) and 224(2).

Referring again to FIG. 4, and also to FIG. 5, in this example, the thermoelectric device 228 is composed of a plurality of thermoelectric-device segments 228S each in thermal contact with the thermal-conduction interface 232 and the heat sink/source 408 on the opposite side of the dissimilar-material junction (not shown, but see junction 120J of FIG. 1) of that thermoelectric-device segment. Adjacent ones of the thermoelectric-device segments 228S are separated by insulation 412 that provides both thermal and electrical insulation. In the example shown, each of the thermoelectric-device segments 228S is in the form of a strip that extends lengthwise in a direction into and out of the pages containing FIGS. 4 and 5. However, in other embodiments, some of the thermoelectric-device segments 228S may be in the form of islands surrounded on all sides by insulation 412. In yet other embodiments, the individual thermoelectric-device segments 228S may be replaced by a single continuous thermoelectric device.

As best seen in FIG. 5, in this example the heat sink/source 408 consists of a flat plate. However, in other embodiments, the heat sink/source 408 may include other structures, such as fins 408F, for increasing the surface area that the flow of air 404 through the air duct 400 contacts. FIG. 5 also illustrates some details of the battery 204. As noted above, in this example the battery 204 is a battery pack, and it is composed of a plurality of individual cells 204I (only a few labeled to avoid cluttering the figure) that are electrically connected to one another in electrical series and/or in electrical parallel to form the core 204C of the battery and so as to provide the battery pack with its design output current and voltage.

In the embodiment shown, due to its construction, the battery 204 needs to be engaged with the thermal-conduction interface 232 in a specific orientation so as to maximize the effectiveness of the thermal management of the battery during charging operations by maximizing the thermal conductance of heat between the battery core 204C and the thermal-conduction interface 232. In this example, the battery 204 has an exterior housing 204H having a bottom wall 204B (relative to FIG. 5), which is the wall of the battery that is designed to contact the thermal-conduction interface 232 of the thermal-management component 224. As can be seen in FIG. 5, the battery core 204C is located proximate to the bottom wall 204B and is secured to the bottom wall using a thermally conductive adhesive 204A so as to provide a continuous thermal pathway from the battery core to the bottom wall.

Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A battery-charging device for charging a secondary battery that includes electrical terminals and a heat-transfer face, the battery-charging device comprising:
a charging region that receives the secondary battery during a charging operations;
a charging system that, when the secondary battery is present in the charging region, electrically connects to the electrical terminals of the secondary battery and charges the secondary battery during the charging operations;
a thermal-management system that includes:
a thermal-conduction interface that contactingly receives the heat-transfer face of the secondary battery when the battery is located in the charging region so that heat can be conducted between the secondary battery and the thermal management system during the charging operations;
a heat sink/source; and
a thermoelectric device thermally coupled between the thermal-conduction interface and the heat sink/source, wherein during the charging operations with the secondary battery located in the charging region, the thermoelectric device transfers heat between the secondary battery and the heat sink/source.

2. The battery-charging device of claim 1, wherein the thermal-conduction interface comprises a thermally conductive contact plate having battery-contacting surface that contacts the heat-transfer face of the secondary battery when the secondary battery is located in the charging region for the charging operations.

3. The battery-charging device of claim 2, comprising a plurality of thermoelectric devices thermally coupled between the thermally conductive contact plate and the heat sink/source.

4. The battery-charging device of claim 3, wherein the thermoelectric devices are spaced apart from one another and thermal insulation is contained in spaces between adjacent ones of the thermoelectric devices.

5. The battery-charging device of claim 1, further comprising an ambient-air heat-transfer system that includes a passageway for providing a flow of ambient air from outside of the battery-charging device to the heat sink/source so as to transfer heat between the flow and the heat sink/source.

6. The battery-charging device of claim 5, wherein the ambient-air heat-transfer system includes a fan for providing the flow of ambient air within the passageway.

7. The battery-charging device of claim 5, wherein the passageway includes an inlet for receiving the ambient air from outside the battery-charging device and an outlet for exhausting the flow of ambient air within the passageway to outside the battery-charging device.

8. The battery-charging device of claim 1, further comprising a control system configured to cause the thermoelectrical device to provide heat to the secondary battery when the secondary battery is at a measured temperature lower than a preset minimum charging temperature.

9. The battery-charging device of claim 8, wherein the control system is further configured to cause the charging system to begin charging once the measured temperature reaches the minimum charging temperature.

10. The battery-charging device of claim 9, wherein the control system is further configured to cause the thermoelectric device to remove heat from the secondary battery when the measured temperature of the secondary battery reaches a preset cooling temperature.

11. The battery-charging device of claim 10, further comprising an ambient-air heat-transfer system that includes:
a passageway for providing a flow of ambient air from outside of the battery-charging device to the heat sink/source so as to transfer heat between the flow and the heat sink/source; and
a fan for providing the flow of ambient air within the passageway;
wherein the control system is further configured to activate the fan in conjunction with causing the thermoelectric device to remove heat from the secondary battery.

12. The battery-charging device of claim 8, further comprising an ambient-air heat-transfer system that includes:
a passageway for providing a flow of ambient air from outside of the battery-charging device to the heat sink/source so as to transfer heat between the flow and the heat sink/source; and
a fan for providing the flow of ambient air within the passageway;
wherein the control system is further configured to activate the fan in conjunction with causing the thermoelectric device to provide heat to the secondary battery.

13. The battery-charging device of claim 1, further comprising a control system configured to cause the thermoelectrical device to remove heat from the secondary battery when the secondary battery is at a measured temperature higher than a preset cooling temperature.

14. The battery-charging device of claim 13, further comprising an ambient-air heat-transfer system that includes:
a passageway for providing a flow of ambient air from outside of the battery-charging device to the heat sink/source so as to transfer heat between the flow and the heat sink/source; and
a fan for providing the flow of ambient air within the passageway;
wherein the control system is further configured to activate the fan in conjunction with causing the thermoelectric device to remove heat from the secondary battery.

15. A method of charging a secondary battery, the method comprising:
causing a battery-charging device to perform charging operations upon the secondary battery; and
during the charging operations, causing a thermoelectric device, that is directly thermally coupled to the secondary battery, to transfer heat between the secondary battery and a heat sink/source by thermal conduction.

16. The method of claim 15, wherein the charging operation includes electrically charging the secondary battery, and the causing of the thermoelectric device to transfer heat between the secondary battery and the heat sink/source includes removing heat from the secondary battery by thermal conduction.

17. The method of claim 16, further comprising measuring a temperature of the secondary battery, and, when the temperature of the secondary battery exceeds a preset cooling temperature, executing the causing of the thermoelectric device to remove heat from the secondary battery.

18. The method of claim 16, further comprising causing a fan to flow ambient air across the heat sink/source so as to remove heat from the heat sink/source.

19. The method of claim 16, further comprising, prior to electrically charging the secondary battery, causing the thermoelectric device to provide heat to the secondary battery.

20. The method of claim 19, further comprising measuring a temperature of the secondary battery, and, when the temperature of the secondary battery is below a preset minimum charging temperature, executing the causing of the thermoelectric device to provide heat to the secondary battery.

21. The method of claim 20, further comprising causing a fan to flow ambient air across the heat sink/source so as to provide heat to the heat sink/source.
